(19) United States
(12) Patent Application Publication
(10) Pub. No.: US 2026/0052908 A1
(43) Pub. Date: Feb. 19, 2026

(54) SURFACE MOUNTABLE PIEZOELECTRIC SHEAR SENSOR AND ACCELEROMETER INCORPORATING SAME

(71) Applicant: MIDE Technology Corporation, Woburn, MA (US)

(72) Inventor: Rob Carter, Arlington, MA (US)

(21) Appl. No.: 19/189,460

(22) Filed: Apr. 25, 2025

Related U.S. Application Data
(60) Provisional application No. 63/684,624, filed on Aug. 19, 2024.

(51) Int. Cl. H10N 30/87; G01P 15/09; H05K 1/18; H10N 30/30; H10N 30/88

(52) U.S. Cl. CPC H10N 30/875; G01P 15/0907; G01P 15/0915; H05K 1/181; H10N 30/302; H10N 30/883; H05K 2201/10151

(57) ABSTRACT

A surface mountable piezoelectric sensor includes a pair of oppositely polarized, spaced, parallel piezoelectric members separated by an isolator. A first electrode is associated with the piezoelectric members bridging the isolator resulting in a series circuit when the pair of piezoelectric members are mounted to a printed circuit board. A second electrode is associated with one piezoelectric member and electrically isolated from a third electrode associated with the other piezoelectric member for surface mounting to the printed circuit board.

### RELATED APPLICATIONS

This application claims benefit of and priority to U.S. Provisional Application Ser. No. 63/684,624 filed Aug. 19, 2024, under 35 U.S.C. §§ 119, 120, 363, 365, and 37 C.F.R. § 1.55 and § 1.78, which is incorporated herein by this reference.

### FIELD OF THE INVENTION

Aspects of this disclosure relate to piezoelectric shear sensors.

### BACKGROUND OF THE INVENTION

Piezoelectric shear sensors, which may be used in accelerometers, typically include a block of piezoceramic material and with a proof mass bonded thereto. See U.S. Pat. Nos. 6,031,317 and 5,521,772 both incorporated herein by this reference. The piezoceramic material is bonded to a printed circuit board which also includes accelerometer circuitry (e.g., one or more signal processing chips, discrete electronic components and the like) configured to, for example, amplify (and/or process, store, output, etc.) the voltage output by the piezoceramic material when it is subject to shear stress to determine the acceleration experience by the printed circuit board. This arrangement may itself be placed in a chip package.

One electrode of the of the piezoceramic shear sensor is typically bonded to a printed circuit board with conductive epoxy which doubles as an electrical contact to the circuit and a mechanical anchor of the sensor to the platform whose acceleration is to be measured. The opposed electrode of the piezoceramic shear sensor must also be connected to the printed circuit so that the electrical potential arising from stress on the piezoceramic during acceleration is accessible to the remote components of the circuit. Typically, this is accomplished by first conductively bonding a metal proof mass to the opposed electrode and, in a second operation, making a wire bond connection from the proof mass down to one of the printed circuit board traces.

This manufacturing process requires two precision bonding operations both of which must result in bonds that simultaneously satisfy stringent mechanical and electrical requirements plus a secondary wire bonding operation. The result is a difficult to manufacture, more costly, and potentially less reliable sensor.

### BRIEF SUMMARY OF THE INVENTION

Featured is an easier to manufacture, less costly, and higher reliability sensor. Also featured is a sensor which is compatible with surface mount technology so that printed circuit board pick and place machines can be used to automate the sensor manufacturing process thus eliminating the need for secondary conductive epoxy and wire bonding operations.

Featured is a surface mountable piezoelectric sensor comprising a pair of oppositely polarized, spaced, parallel piezoelectric members separated by an isolator, a first electrode associated with the piezoelectric members bridging the isolator resulting in a series circuit when the pair of piezoelectric members are mounted to a printed circuit board, and a proof mass. A second electrode is associated with one piezoelectric member and electrically isolated from a third electrode associated with the other piezoelectric member for surface mounting to the printed circuit board.

In some examples, the second electrode is isolated from the third electrode by the isolator. Each piezoelectric member can be a cuboid and the isolator can also be a cuboid. The proof mass can be bonded to the first electrode. The proof mass can be conductive.

In some examples, the second electrode is on a bottom face of one piezoelectric member and the third electrode is on a bottom face of the other piezoelectric member. The top and bottom faces of each piezoelectric member can be metallized. In one example, the isolator is an insulating ceramic material.

For a shear sensor, the piezoelectric members are oppositely polarized along one axis of sensitivity and for a compression sensor, the piezoelectric members are oppositely polarized along a different axis of sensitivity.

Also featured is an accelerometer comprising a printed circuit board, and accelerometer circuitry connected via the printed circuit board to at least one of first and second spaced surface mount pads on the printed circuit board. A surface mounted piezoelectric sensor includes first and second differently polarized piezoelectric members separated by an isolator, a first electrode connecting the piezoelectric members across the isolator, a proof mass, a second electrode associated with the first piezoelectric member mounted to one of the first and second spaced surface mount pads on the printed circuit board, and a third electrode associated with the second piezoelectric member and isolated from the second conductive electrode and surface mounted to the other of the first and second spaced surface mount pads on the printed circuit board.

Also featured is a surface mountable piezoelectric sensor with a pair of piezoelectric members separated by an isolator, a proof mass associated with the piezoelectric members, one piezoelectric member includes a bottom negative terminal and the other piezoelectric member includes a bottom positive terminal electrically isolated from the bottom negative terminal for surface mounting to a printed circuit board. One piezoelectric member includes a top positive terminal and the other piezoelectric member includes a top negative terminal electrically connected to said top positive terminal.

Also featured is a surface mountable piezoelectric sensor comprising first and second piezoelectric members separated by an isolator, a proof mass associated with the piezoelectric members, the first piezoelectric member includes a negative terminal and the second piezoelectric member includes a positive terminal for surface mounting to a printed circuit board, and the first piezoelectric member includes a positive terminal electrically connected to a negative terminal of the second piezoelectric member.

The subject invention, however, in other embodiments, need not achieve all these objectives and the claims hereof should not be limited to structures or methods capable of achieving these objectives.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic exploded view of an example of a shear sensor in accordance with aspects of the disclosure;

FIG. 2 is a view of an assembled sensor ready for placement on a printed circuit board; and

FIG. 3 is an exploded schematic view of a compression sensor in accordance with aspects of the disclosure.

### DETAILED DESCRIPTION OF THE INVENTION

A side from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

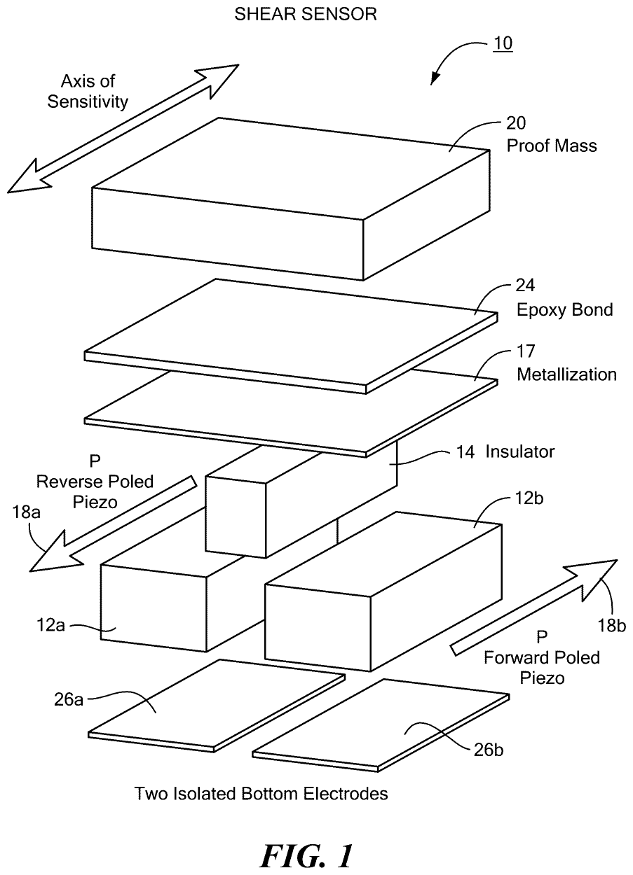

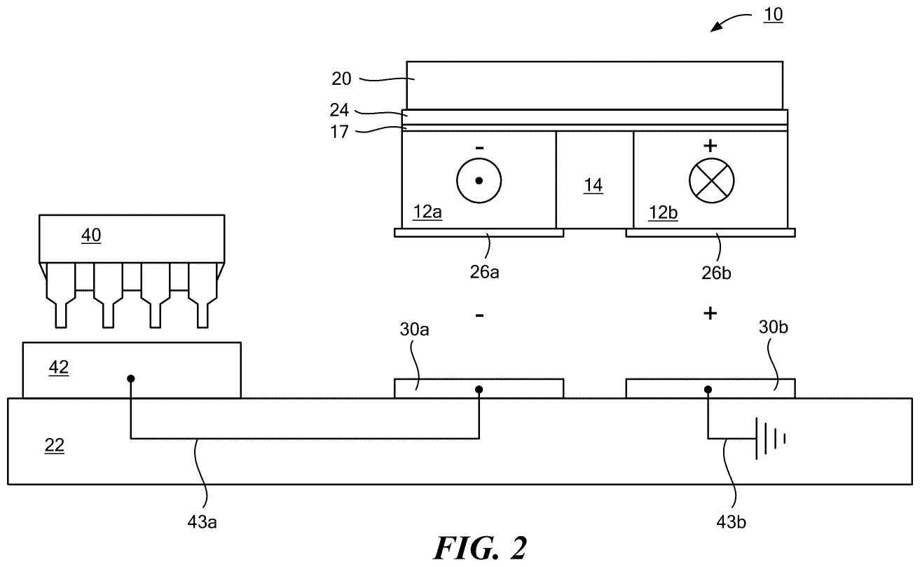

In one example, a surface mountable piezoelectric shear sensor 10, FIGS. 1-2 includes adjacently spaced, parallel, oppositely polarized piezoelectric (e.g., piezoceramic) members 12a, 12b (e.g., cuboids having the same size and shape), FIGS. 1-2, separated by isolator 14 (also e.g., a cuboid) made of an insulating ceramic in some examples. In the example shown, piezoelectric member 12a is polarized in the direction shown by arrow 18a and piezoelectric member 12b is polarized in the opposite direction shown by arrow 18b (usually both parallel to the major horizontal faces of members 12a, 12b). Conductive electrode material 17 may be sputtered on piezoelectric member 12a, on isolator 14, and on piezoelectric member 12b as shown forming an electrode extending from piezoelectric member 12a, across isolator 14, and to piezoelectric member 12b. Proof mass 20 (e.g., steel or tungsten) is coupled (e.g., bonded by epoxy 24) to both of piezoelectric members 12a, 12b bridging the isolator 14 and covering the entirety of the composite surface.

In some embodiments, epoxy 24 can be conductive as is mass 20 which spans the isolator to form a circuit connecting the positive and negative terminals of piezoelectric members 12a, 12b.

Conductive electrode material 26a can be sputtered onto the bottom face of piezoelectric member 12a and conductive electrode material 26b can be sputtered onto the bottom face of piezoelectric member 12b forming electrodes isolated from each other by isolator 14.

The result is a series circuit producing an electrical potential difference between electrodes 26a, 26b when the piezoelectric members are mounted to printed circuit board 22 and subject to a shear force such as acceleration. Proof mass 20 is generally fairly thin and of uniform thickness.

Each piezoelectric member 12a, 12b has a conductive electrode 26a, 26b, respectively, formed thereon (e.g., by metallization, printing, etc.) (e.g., gold or aluminum or another conductive metal) on the bottom surface/face of each piezoelectric member. On the top surface/face of the assembled sensor the piezoelectric members and spacer share a common electrode 24 achieved via metallization and/or conductive epoxy bond to a metal proof mass.

In FIG. 2, assembled sensor 10 is shown ready for placement on printed circuit board 22 including spaced surface mount pads 30a, 30b using, for example, a pick and place machine and surface mount soldering techniques. Thus, the sensor electrode 26a (a positive output terminal) electrically and physically couples to pad 30a and separate electrode 26b (a negative output terminal) electrically and physically couples to pad 30b.

Printed circuit board 22 may also be populated with accelerometer circuitry 40 mounted to printed circuit board surface mount pad 42. Circuitry 40 may include one or more chips, circuit components and the like for signal amplification, signal processing, computational functions, and the like.

In the example shown, the negative terminal 26b of piezoelectric member 12b is connected to ground via printed circuit board 22 and the positive terminal 26a of piezoelectric member 12a is connected to circuitry 40 via printed circuit board 22. In FIG. 2, PCB trace 43a electrically connects pad 42 to pad 30a and pad 30b is connected to ground via trace 43b.

The series connection of the piezoelectric members is shown with a negative terminal of piezoelectric member 12a electrically connected via mass 20 and/or conductive epoxy 24 and/or metallization 17 to the positive terminal of piezoelectric member 12b. Or, the negative terminal of piezoelectric member 12a is electrically connected to the positive terminal of piezoelectric member 12b via an electrode as discussed above in which case epoxy 24 may be insulative.

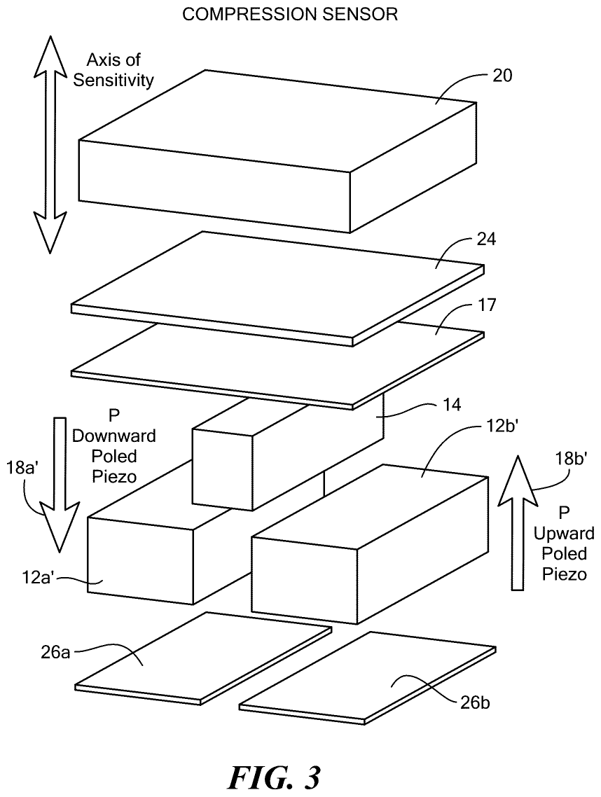

Analogous piezoelectric structures can be made that sense compressive stress (i.e. perpendicular to the plane of the proof mass) by utilizing pairs of piezoceramic elements 12a′, 12b′ FIG. 3 with polarization directions perpendicular to the plane of the major surfaces of members 12a′, 12b′. This configuration can also be assembled to a printed circuit board by pick and place surface mount equipment without need of secondary conductive adhesive and wire bonding operations.

Additional piezoelectric sensors may be placed on the printed circuit board to sense acceleration in additional (e.g., orthogonal) axes. The resulting structure may then be packaged in a chip package. In other examples, a circuit board of some other system may be configured to now include the acceleration sensor(s). Examples include embedded health monitoring systems or internet of things devices and systems.

In one preferred embodiment, wire bonding and/or extensive gluing operations are eliminated. The result is an easier to manufacture and a more cost efficient sensor.

An exemplary assembled piezoceramic-insulator-piezoceramic laminate in one example would measure 1 mm in the vertical dimension and 3 to 5 mm on a side. A typical steel proof mass would match and mate to the 3 to 5 mm dimension and would be 0.5 to 1.5 mm thick.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments. Other embodiments will occur to those skilled in the art and are within the following claims.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant cannot be expected to describe certain insubstantial substitutes for any claim element amended.

What is claimed is:

1. A surface mountable piezoelectric sensor comprising:
a pair of oppositely polarized, spaced, parallel piezoelectric members separated by an isolator;
a first electrode associated with the piezoelectric members bridging the isolator resulting in a series circuit when the pair of piezoelectric members are mounted to a printed circuit board;
a proof mass; and
a second electrode associated with one piezoelectric member electrically isolated from a third electrode associated with the other piezoelectric member for surface mounting to the printed circuit board.

2. The sensor of claim 1 in which the second electrode is isolated from the third electrode by the isolator.

3. The sensor of claim 1 in which each piezoelectric member is a cuboid.

4. The sensor of claim 3 in which the isolator is also a cuboid.

5. The sensor of claim 1 in which the proof mass is bonded to the first electrode.

6. The sensor of claim 1 in which the proof mass is conductive.

7. The sensor of claim 1 in which the second electrode is on a bottom face of one piezoelectric member and the third electrode is on a bottom face of the other piezoelectric member.

8. The sensor of claim 7 in which the top and bottom faces of each piezoelectric member are metallized.

9. The sensor of claim 1 in which the isolator is an insulating ceramic material.

10. The sensor of claim 1 in which the piezoelectric members are oppositely polarized along an axis of sensitivity forming a shear sensor.

11. The sensor of claim 1 in which the piezoelectric members are oppositely polarized along an axis of sensitivity forming a compression sensor.

12. An accelerometer comprising:
a printed circuit board;
accelerometer circuitry connected via the printed circuit board to at least one of first and second spaced surface mount pads on the printed circuit board; and
a surface mounted piezoelectric sensor including:
first and second differently polarized piezoelectric members 6 separated by an isolator,
a first electrode connecting the piezoelectric members across the isolator,
a proof mass,
a second electrode associated with the first piezoelectric member and surface mounted to one of the first and second spaced surface mount pads on the printed circuit board, and
a third electrode associated with the second piezoelectric member and isolated from the second conductive electrode and surface mounted to the other of the first and second spaced surface mount pads on the printed circuit board.

13. The accelerometer of claim 12 in which the third electrode is isolated from the second electrode by the isolator.

14. The accelerometer of claim 12 in which each piezoelectric member is a cuboid.

15. The accelerometer of claim 14 in which the isolator is also a cuboid.

16. The accelerometer of claim 12 in which the proof mass is bonded to first electrode.

17. The accelerometer of claim 12 in which the proof mass is conductive.

18. The accelerometer of claim 12 in which each piezoelectric member has a top and bottom face conductive electrode.

19. The accelerometer of claim 18 in which the top and bottom faces of the piezoelectric members are metallized.

20. The accelerometer of claim 12 in which the isolator is an insulating ceramic material.

21. A surface mountable piezoelectric sensor comprising:
a pair of piezoelectric members separated by an isolator;
a proof mass associated with the piezoelectric members;
one piezoelectric member including a bottom negative terminal and the other piezoelectric member including a bottom positive terminal electrically isolated from the bottom negative terminal for surface mounting to a printed circuit board; and
one piezoelectric member including a top positive terminal and the other piezoelectric member including a top negative terminal electrically connected to said top positive terminal.

22. A surface mountable piezoelectric sensor comprising:
first and second piezoelectric members separated by an isolator;
a proof mass associated with the piezoelectric members;
the first piezoelectric member including a negative terminal and the second piezoelectric member including a positive terminal for surface mounting to a printed circuit board; and
the first piezoelectric member including a positive terminal electrically connected to a negative terminal of the second piezoelectric member.
